(19) United States
(12) Patent Application Publication
(10) Pub. No.: US 2006/0121260 A1
(43) Pub. Date: Jun. 8, 2006

(54) Laminated sheet and a method for manufacturing the laminated sheet

(75) Inventors: Steve Shi Lin, Sunnyvale, CA (US); Sunder Ram, San Jose, CA (US)

Correspondence Address: William L. Botjer, PO Box 478, Center Moriches, NY, 11934, US

(73) Assignee: FLEXICS, INC.

(21) Appl. No.: 11/004,213

(22) Filed: Dec. 3, 2004

(51) Int. Cl. B32B 27/00; B32B 37/00

(52) U.S. Cl. 428/220; 428/411.1; 156/286; 156/382

(57) ABSTRACT

A laminated sheet, particularly suitable for use in TFT fabrication, and a method for manufacturing it. The laminated sheet includes a flexible substrate, a rigid carrier, and a laminate. The method for manufacturing it involves the steps of outgassing the laminate, forming a laminated sheet by laminating the flexible substrate to the rigid carrier by means of the laminate, and degassing the laminated sheet.

### BACKGROUND

The present invention relates generally to display panels, and more particularly to the use of flexible substrates as backplanes for Liquid Crystal Displays (LCDs) and Organic Light Emitting Displays (OLEDs).

Conventional display technology involves the fabrication of large arrays of thin film transistors (TFTs) on glass substrate. TFT fabrication using an amorphous silicon (a-Si) consists of several vacuum process steps. These process steps include the use of Plasma Enhanced Chemical Vapor Deposition (PECVD) for deposition of an a-Si and a gate dielectric insulation layer. The process steps also include the use of sputtering equipment for deposition of both data and scan metal lines, and Indium Tin Oxide (ITO) layers. For the formation of polycrystalline silicon TFTs, an a-Si is crystallized to form polycrystalline silicon (poly-Si) with a pulsed energy source such as an excimer laser. The fabrication process of poly-Si TFTs is more complicated than that of a-Si TFTs, and includes extra steps, such as an activation process, for ion doping. In order to structure the various layers, the patterning steps use common lithographic equipment such as resist coaters, aligners, and dry or wet etching equipment. The TFT substrate is then assembled with other electronic devices to form an LCD panel, or it is deposited with the OLED and barrier layers to form an OLED panel.

For a number of applications, it is desirable to have display panels fabricated on flexible substrates instead of glass. Flexible substrates offer various advantages over glass substrates, e.g., they are very thin, lightweight, and shatterproof. However, it is difficult to fabricate TFTs directly on flexible substrates because flexible substrates have less dimensional and thermal stability, compared to glass substrates. Moreover, handling a flexible substrate with precision is not easy. This makes the flexible substrate incompatible for conventional TFT fabrication processes. The problems mentioned above are solved by laminating the flexible substrate onto a rigid carrier before fabricating TFTs over it. The lamination is temporary and can be removed after the fabrication process is complete. High Performance TFTs on flexible substrates can be obtained after removing the laminate and the rigid carrier.

Various methods have been provided in the prior art for manufacturing a laminated sheet for different display applications. A laminated sheet typically includes a plastic substrate, an adhesive, and a rigid carrier. The rigid carrier is generally made of glass.

Japanese Patent Number JP7325297A2, entitled ‘Laminated Sheet with Plastic Substrate and Treatment of Substrate’, assigned to Fujimori Kygyo K K and Seiko Epson Corp., describes a laminated sheet and a method for manufacturing the same. The laminated sheet consists of a plastic substrate, a glass plate, and an adhesive layer. The adhesive layer is placed between the plastic substrate and the glass plate. The method of manufacturing a laminated sheet involves fixing the plastic substrate and the glass plate on both surfaces of the adhesive layer. Since the adhesive layer loses its adhesive power when subjected to UV rays, delamination is carried out by irradiating the laminated sheet with UV rays.

Japanese patent Number JP2002055330A2, entitled ‘Method for Manufacturing Laminated Sheet for Liquid Crystal Display Panel’, assigned to Seiko Epson Corp., Panac Co. Ltd., and Bando Chem Ind Ltd., describes a laminated sheet consisting of a translucent plastic film, an adhesive sheet, and a fixing substrate. The adhesive sheet described in the patent consists of a substrate resin sheet, which has a UV-curing adhesive layer on one surface and an adhesive layer on the other. The method of manufacturing the laminated sheet involves fixing the plastic film to the UV-curing adhesive layer and fixing of the substrate to the adhesive layer. For delamination, the laminated sheet is subjected to UV rays, so that the UV-curing adhesive layer loses its adhesive properties and the plastic film can be easily removed from the laminated sheet.

Another method has been provided in Japanese Patent Number JP2001027753A2, entitled ‘Production of Laminated Sheet for Liquid Crystal Display Panel and Production of Liquid Crystal Display Panel’, assigned to Bando Chem Ind Ltd., Seiko Epson Corp., and Panac Co. Ltd. The method for manufacturing the laminated sheet involves placing a light-transmitting plastic layer on an adhesive sheet and rolling them together. Heat and pressure are applied through the roll so that the light-transmitting plastic layer attaches itself firmly to the adhesive sheet. The adhesive sheet described in the patent consists of a base resin sheet and an adhesive layer.

The methods described above suffer from one or more of the following limitations. First, the laminated sheet described uses an adhesive layer that loses its adhesive power when irradiated with UV rays. This may result in the laminated sheet being delaminated while fabricating TFTs, since it is exposed to UV radiations during the TFT fabrication process. Second, the methods produce laminated sheets that release trapped gases at high vacuum during TFT fabrication processes. This release of volatiles results in cross-contamination, therefore outgassing of the adhesive layer needs to be carried out prior to the lamination process. Third, it is difficult to achieve a bubble-free lamination by just fixing a plastic substrate and a glass plate on either sides of the adhesive layer. To remove the air bubbles, another adhesive sheet and resin sheet can be used in the laminated sheet. However, this makes the control of dimensional stability difficult, due to a mismatch in the coefficient of thermal expansion of different materials.

Hence, there is a need for a laminated sheet that has the required dimensional stability during TFT processing. The laminated sheet should also have the property of low outgassing at high vacuum. Further, the laminated sheet should be moisture-free and should have good chemical compatibility.

### SUMMARY

It is an object of the present invention to provide a laminated sheet that has the required dimensional stability during the TFT fabrication process.

Another object of the present invention is to provide a laminated sheet that has the property of low outgassing at high vacuum.

Another object of the present invention is to provide a laminated sheet that has good chemical compatibility during the TFT fabrication process.

The present invention provides a laminated sheet and a method for manufacturing it. The laminated sheet consists of a flexible substrate, a glass carrier, and a laminate. The laminate is non-reactive and thermoplastic. Further, it is placed in between the flexible substrate and the glass carrier, and holds them together.

The method for manufacturing the laminated sheet includes the steps of outgassing the laminate, laminating the flexible substrate on the glass carrier, and degassing the laminated sheet. Outgassing is carried out to remove trapped air and volatiles from the substrate. Degassing is carried out to remove moisture from the laminated sheet.

### BRIEF DESCRIPTION OF THE DRAWINGS

The various embodiments of the present invention will hereinafter be described in conjunction with the appended drawings, provided to illustrate and not to limit the present invention, wherein like designations denote like elements, and in which:

FIG. 1 illustrates an exemplary Organic Light Emitting Display (OLED) panel;

FIG. 2 illustrates a laminated sheet, in accordance with an embodiment of the present invention;

FIG. 3 illustrates a laminated sheet, in accordance with another embodiment of the present invention;

FIG. 4 is a flowchart illustrating the method for manufacturing the laminated sheet, in accordance with an embodiment of the present invention;

FIG. 5 is a flowchart illustrating the method for outgassing the laminate, in accordance with an embodiment of the present invention;

FIG. 6 is a flowchart illustrating the method for laminating the flexible substrate with the rigid carrier, in accordance with an embodiment of the present invention;

FIG. 7 is a block diagram illustrating a system for manufacturing the laminated sheet, in accordance with an embodiment of the present invention.

### DESCRIPTION OF THE PREFFERED EMBODIMENTS

The present invention describes a laminated sheet and a method for manufacturing the laminated sheet. The laminated sheet includes a flexible substrate, a rigid carrier, and a laminate. The method for manufacturing the laminated sheet includes outgassing the laminate, laminating the flexible substrate onto the rigid carrier to form a laminated sheet, and degassing the laminated sheet.

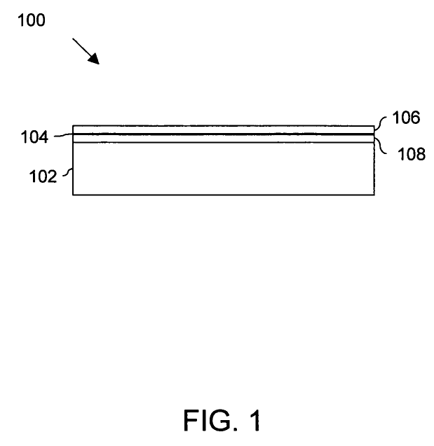

FIG. 1 illustrates an exemplary Organic Light Emitting Display (OLED) panel 100. OLED panel 100 includes a flexible substrate 102, a layer of OELD 104, and a moisture and gas barrier layer 106. The use of flexible substrate 102 makes OLED panel 100 lightweight, thin, and shatterproof. Flexible substrate 102 may be a plastic sheet or a stainless steel coil. Flexible substrate 102 also has a TFT array 108 fabricated over it. TFT array 108 is fabricated by using a very thin layer of semiconductor material that is deposited on flexible substrate 102. In order to provide thermal and dimensional stability to flexible substrate 102, it is laminated onto a rigid carrier to form a laminated sheet.

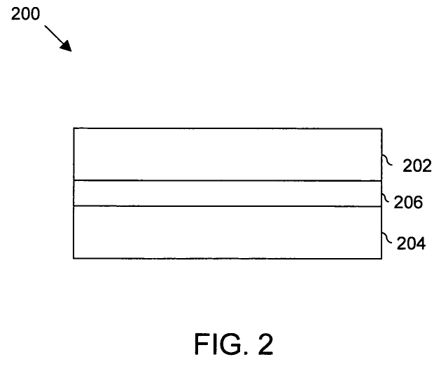

FIG. 2 illustrates a laminated sheet 200, in accordance with an embodiment of the present invention. Laminated sheet 200 includes a flexible substrate 202, a rigid carrier 204, and a laminate 206. Flexible substrate 202 may be a plastic sheet or a stainless steel coil. Rigid carrier 204 provides rigidity and good dimensional stability to flexible substrate 202. Rigid carrier 204 may be a glass plate, a ceramic plate, or a silicon plate. Laminate 206 binds flexible substrate 202 to rigid carrier 204 during the TFT fabrication processes.

Laminate 206 is non-reactive. Unlike reactive laminates, which cause internal stress during the TFT fabrication processes, a non-reactive laminate provides the required dimensional and thermal stability to laminated sheet 200. Further, laminate 206 has a bonding temperature of more than 130° C., which provides thermal stability to laminated sheet 200 during the TFT fabrication processes.

Laminate 206 may have a thickness of 75 to 150 microns, in accordance with an embodiment of the present invention. A thickness of less than 75 microns may cause voids to be formed in laminated sheet 200 during the lamination process. If the thickness is more than 150 microns, degassing of laminate 206 and thickness uniformity control of laminated sheet 200 becomes difficult.

Laminate 206 may be thermoplastic, in accordance with an embodiment of the present invention. The thermoplastic characteristic of laminate 206 makes the lamination temporary, as the laminate softens on heating and gets delaminated. This property allows adhesives to be used as temporary laminates. Further, in accordance with an embodiment of the present invention, laminate 206 may be in the form of a film, which makes the processing of laminate 206 easy, as it can be die-cut. The film form has less outgassing and contamination. It also allows the thickness of laminate 206 to be more consistent and uniform.

In an embodiment of the present invention, laminate 206 is based on Ethylene Vinyl Acetate (EVA). In another embodiment of the present invention, laminate 206 is based on polyester. In an exemplary embodiment of the present invention, laminate 206 is polyester based thermoplastic adhesive bonding film 668 with 100 microns film thickness, from 3M™. In another exemplary embodiment of the present invention, laminate 206 is EVA based thermoplastic adhesive bonding film 557 with 100 microns film thickness, from 3M™.

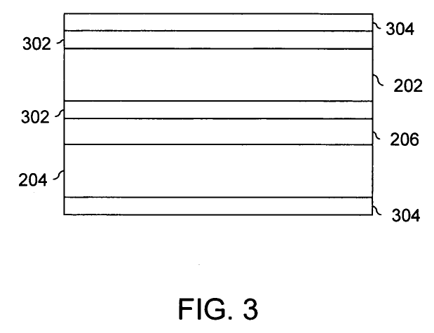

FIG. 3 illustrates a laminated sheet, in accordance with another embodiment of the present invention. Here, flexible substrate 202 is coated with a barrier coating 302 on either side. Barrier coating 302 acts as an anti-scratch coating, preventing the surface of flexible substrate 202 from being scratched. It also smoothens the surface of flexible substrate 202 and acts as a moisture barrier. Barrier coating 302 may be a hybrid of organic and inorganic polymers. In an exemplary embodiment of the present invention, barrier coating 302 is a polysiloxane coating.

In another embodiment of the present invention, a release fabric 304 is placed on either side of laminated sheet 200. For lamination, the pressure is applied through release fabric 304 in the vacuum laminator, so as to prevent any excess laminate from contaminating flexible substrate 202 and laminator surfaces, while pressure is being applied. During the lamination procedure, release fabric 304 remains in contact with the pressure-applying mechanism in the vacuum laminator. Release fabric 304 may not leave a fabric mark on the surface of flexible substrate 202. Further, it may allow volatiles and trapped air to escape from laminated sheet 200. Suitable release fabrics include glass fiber, nylon, and polyester materials coated with a release agent. In an embodiment of the present invention, release fabric 304 is release ease 234 TFP from Airtech International Inc., which is a porous PTFE-coated glass fabric.

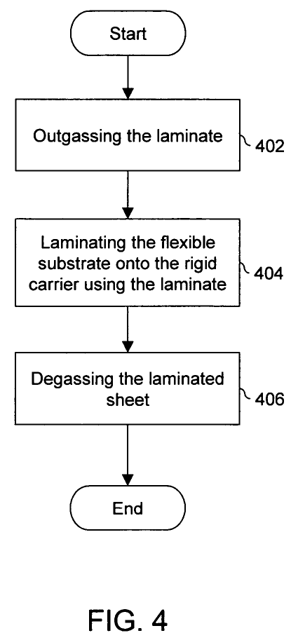

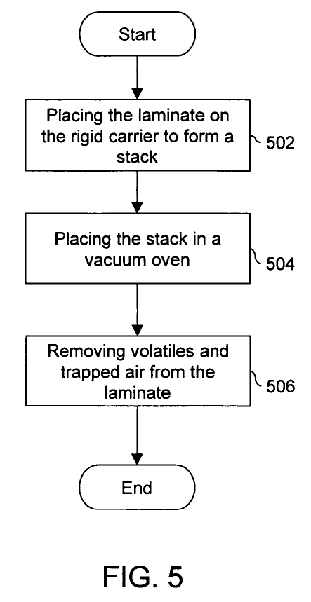

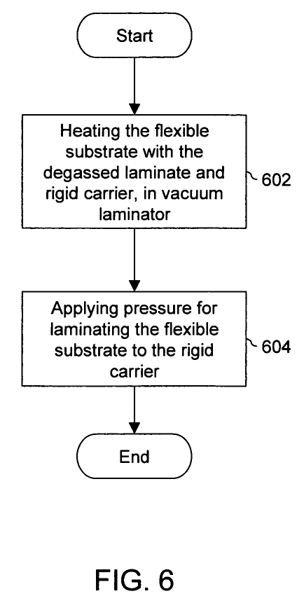

FIG. 4 is a flowchart illustrating a method for manufacturing laminated sheet 200, in accordance with an embodiment of the present invention. At step 402, laminate 206 is outgassed in a vacuum oven. During outgassing, volatiles and trapped air are released from laminate 206. This step prevents the formation of voids in laminated sheet 200 during the lamination procedure. The method of outgassing is described in detail in conjunction with FIG. 5. At step 404, flexible substrate 202 is laminated to rigid carrier 204 by using laminate 206 to form laminated sheet 200. The method of lamination is described in detail in conjunction with FIG. 6. At step 406, laminated sheet 200 is degassed in a vacuum oven to remove entrapped moisture. For degassing, a pressure of less than 30 mTorr and a temperature ranging from 45 to 125° C. is maintained for 16 hours in the vacuum oven. After the lamination procedure, laminated sheet 200 may be stored in a vacuum storage oven at a temperature ranging from 45 to 100° C. to perform the TFT fabrication processes.

FIG. 5 is a flowchart illustrating the method for outgassing laminate 206, in accordance with an embodiment of the present invention. At step 502, laminate 206 is placed on rigid carrier 204 to form a stack. At step 504, the stack is placed in a vacuum oven. At step 506, volatiles and trapped air are removed from the stack of laminate 206 and rigid carrier 204. For this purpose, a pressure ranging from 10 to 200 mTorr and a temperature ranging from 95 to 125° C. is maintained in the vacuum oven for 72 hours. The stack may be kept in a vacuum oven for storage purposes before the lamination procedure is performed, in accordance with an embodiment of the present invention.

FIG. 6 is a flowchart illustrating a method for laminating flexible substrate 202 onto the stack of laminate 206 and rigid carrier 204, in accordance with an embodiment of the present invention. At step 602, flexible substrate 202 is heated in a vacuum laminator with the stack of degassed laminate 206 and rigid carrier 204. The temperature of the vacuum laminator is increased until it reaches a maximum temperature. The maximum temperature depends on the properties of laminate 206. To reduce stress, the maximum temperature may be kept close to the softening temperature of laminate 206. The temperature profile is important for minimizing stress in laminated sheet 200. The temperature in the vacuum laminator may be increased in small steps until the maximum temperature is reached, so as to control the stress in laminated sheet 200. At step 604, a pressure ranging from 660 to 760 Torr is applied on the stack of flexible substrate 202, laminate 206, and rigid carrier 204. The pressure is applied through pair of release fabric 304, so as to laminate flexible substrate 202 to rigid carrier 204. In an embodiment of the present invention, flexible substrate 202 may be degassed in a vacuum oven, before lamination, to remove moisture. For degassing, the temperature may be maintained at 40° C. or higher under a pressure of 20 mTorr or lower for 16 hours.

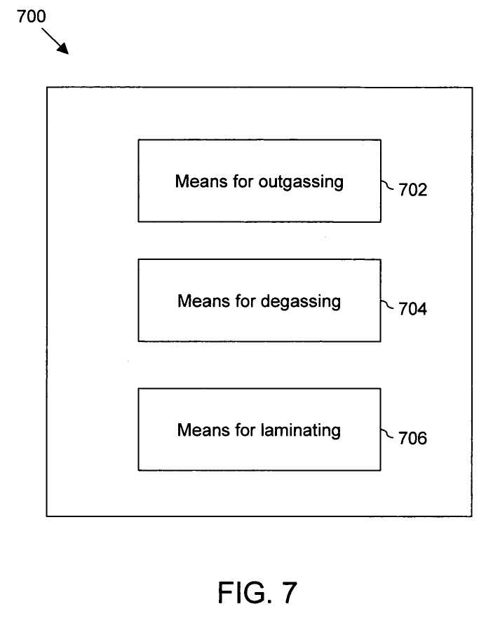

FIG. 7 is a block diagram illustrating a system 700 for manufacturing laminated sheet 200. System 700 includes means for outgassing 702, means for degassing 704, and means for laminating 706. Means for outgassing 702 may be a vacuum oven. Means for degassing 704 may also be a vacuum oven. Means for laminating 706 may be hydraulic or mechanical press lamination, vacuum press lamination, oven-bonding lamination, hot shoe or thermode-bonding lamination, or heat roll lamination with or without vacuum. Lamination in a vacuum is preferred for the lamination procedure described above. Vacuum ovens may be used for storing laminated sheet 200, in accordance with an embodiment of the present invention.

In an embodiment of the present invention, laminate 206 is polyester-based 668 laminate film from 3M™, which has a softening temperature in the range of 149 to 160° C. For lamination, the initial temperature of the vacuum laminator is kept at 110° C., and the maximum temperature at 150° C. The temperature is increased in five steps, each temperature being maintained in the vacuum laminator for a specific period of time. The lamination starts at 110° C. This temperature is maintained for 10 minutes, after which it is increased to 130° C. over a time period of 10 minutes. It is kept at 130° C. for the next five minutes after which it is further increased to 150° C. over a time period of 10 minutes, and kept at 150° C. for another 10 minutes. The laminator is then vented and the temperature is lowered to 110° C. Laminated sheet 200 is then degassed at 90° C. at a pressure of less than 30 mTorr for 16 hours in a vacuum oven. It is then stored in the vacuum oven at 45° C. for the TFT fabrication process.

An advantage of the laminated sheet and the method for manufacturing it, as described in the present invention, is that it has the required thermal and dimensional stability. The flexible substrate retains dimensions within ±60 ppm distortion when attached to the rigid carrier. Another advantage is that the laminated sheet has low outgassing properties at high vacuum. It has an outgassing of 5*10⁻⁵ Torr-liter/sec or less at 50° C., and an outgassing of 2*10⁻⁴ Torr-liter/sec or less at 90° C. Another advantage is that the laminated sheet has good chemical compatibility. A further advantage is that the laminated sheet has uniform thickness, which is not more than 1.00 mm and has a tolerance of ±0.020 mm or less.

While the various embodiments of the present invention have been illustrated and described, it will be clear that the present invention is not limited only to these embodiments. Numerous modifications, changes, variations, substitutions, and equivalents will be apparent to those skilled in the art, without departing from the spirit and scope of the present invention, as described in the claims.

What is claimed is:

1. A method for manufacturing a laminated sheet, the laminated sheet being used for thin film transistor (TFT) fabrication, the laminated sheet comprising a flexible substrate, a rigid carrier and a laminate, the method comprising the steps of:
a. outgassing the laminate;
b. laminating the flexible substrate to the rigid carrier using the laminate to form the laminated sheet; and
c. degassing the laminated sheet.

2. The method according to claim 1 further comprising the step of storing the laminated sheet in vacuum at a temperature ranging from 45 to 100° C., before performing the TFT fabrication.

3. The method according to claim 1 wherein the step of outgassing of the laminate comprises the steps of:
a. placing the laminate on the rigid carrier to form a stack;
b. placing the stack in a vacuum oven; and
c. degassing the stack at a temperature ranging from 95 to 125° C. for 72 hours at a pressure of 200 mTorr or less.

4. The method according to claim 1 wherein the step of laminating the flexible substrate to the rigid carrier comprises the steps of:
a. heating the flexible substrate together with the laminate and the rigid carrier in a vacuum laminator until the bonding temperature is reached; and
b. applying pressure for laminating the flexible substrate to the rigid carrier wherein the pressure ranges from 660 Torr to 760 Torr.

5. The method according to claim 1 wherein the step of degassing the laminated sheet comprises the steps of:
a. placing the laminated sheet in a vacuum oven; and
b. removing moisture from the laminated sheet by applying a pressure of less than 30 mTorr and a temperature ranging from 45 to 125° C. for 16 hours.

6. The method according to claim 1 wherein the laminate has a thickness ranging from 75 microns to 150 microns.

7. The method according to claim 1 wherein the laminate is thermoplastic.

8. The method according to claim 1 wherein the laminate is in film form.

9. A laminated sheet for use in thin film transistor (TFT) fabrication, the laminated sheet comprising:
a. a flexible substrate, the flexible substrate enabling TFT fabrication over it;
b. a rigid carrier, the rigid carrier providing dimensional stability to the flexible substrate during TFT fabrication processes; and
c. a laminate, the laminate binding the flexible substrate to the rigid carrier, the laminate being non-reactive and having a bonding temperature of more than 130° C.

10. The laminated sheet according to claim 9 wherein the laminate has a thickness of 75 microns to 150 microns.

11. The laminated sheet according to claim 9 wherein the laminate is thermoplastic.

12. The laminated sheet according to claim 9 wherein the laminate is in film form.

13. The laminated sheet according to claim 9 wherein the flexible substrate has a barrier coating on either of its surface for making the surface of the flexible substrate smooth and scratch proof.

14. The laminated sheet according to claim 9 further comprising two layers of release fabrics, each layer being placed on the either side of the laminated sheet, the release fabric being used for preventing marks on the laminated sheet during the application of pressure for lamination in the vacuum laminator.

15. A system for manufacturing a laminated sheet, the laminated sheet being used for TFT fabrication, the laminated sheet comprising a flexible substrate, a rigid carrier and a laminate, the system comprising:
a. means for outgassing the laminate;
b. means for laminating the flexible substrate to the rigid carrier using the laminate to form the laminated sheet; and
c. means for degassing the laminated sheet.

16. The system according to claim 15 wherein the means for outgassing is a vacuum oven.

17. The system according to claim 15 wherein the means for laminating is selected from the group consisting of hydraulic press lamination, mechanical press lamination, vacuum press lamination, oven-bonding lamination, hot shoe lamination, thermode-bonding lamination, and heat roll lamination.

18. The system according to claim 15 wherein the means for degassing is a vacuum oven.
